(19) United States
(12) Patent Application Publication
(10) Pub. No.: US 2002/0053401 A1
(43) Pub. Date: May 9, 2002

(54) Organic luminescence display device and process for production thereof

(76) Inventors: Nobuyuki Ishikawa, Yokohama-shi (JP); Issei Yonemoto, Yamato-shi (JP); Satoko Midorikawa, Tokyo (JP); Yasuyuki Saito, Kawasaki-shi (JP)

Correspondence Address: FITZPATRICK CELLA HARPER & SCINTO, 30 ROCKEFELLER PLAZA, NEW YORK, NY, 10112, US

(21) Appl. No.: 09/984,722

(22) Filed: Oct. 31, 2001

(30) Foreign Application Priority Data
Oct. 31, 2000 (JP) 331726/2000
Oct. 23, 2001 (JP) 325092/2001

(51) Int. Cl. C09J 5/02

(52) U.S. Cl. 156/309.3; 156/309.9

(57) ABSTRACT

An organic luminescence device including organic layers disposed between an anode and a cathode is produced through a process including: a step of forming a first organic layer over an anode already formed on a first substrate; a step of forming a second organic layer comprising an identical material forming the first organic layer over a cathode already formed on a second substrate; and a combining step of disposing the first and second organic layers opposite to each other and applying the first and second organic layer to each other under pressure, followed by baking, to form a laminate organic luminescence device. A step of pre-baking at least one of the first and second organic layers is preferably included prior to the combining step. As a result, the organic layers in the luminescence device can be formed free from binders and yet in a good adhesion therebetween.

### FIELD OF THE INVENTION AND RELATED ART

The present invention relates to an organic luminescence (display) device formed by application of separately prepared two substrates and a process for production thereof.

An organic luminescence device (hereinafter sometimes also called an “organic EL device”) has a structure including a cathode, an anode, and a film comprising a fluorescent organic compound sandwiched between the cathode and the anode. In the organic luminescence device, electron and holes are injected into the film and re-combined therein to form excitons, which are then caused to emit light (fluorescence or/and phosphorescence) at the time of deactivation thereof thus causing luminescence.

Such an organic EL device is characterized by a capability of luminescence at a high luminance on the order of 10²-10⁵ cd/m² at a low voltage of 10 vols or lower and also by a capability of blue to red luminescence by selection of fluorescent materials.

The organic EL device has called an attention for realization of an inexpensive large-area full-color display device (“Denshi Jouhou Tsushin Gakkai Gijutsu Houkoku (Electronic Data Communication Society Technical Reports)”, Vol. 89, No. 106, page 49 (1989)). According to the report, bright luminescences of blue, green and red have been obtained by using organic dyes emitting strong fluorescences in the luminescence layers. It is considered that such a high-luminance full-color display could be realized by using thin films of organic dyes capable of emitting strong luminescences and with few pinhole defects.

Further, Japanese Laid-Open Patent Application (JP-A) 5-78655 has proposed to form a thin film of organic luminescence layer comprising a mixture of an organic charge-transporting material and an organic luminescent material so as to prevent density extinction, thereby broadening the latitude of selection of luminescent, for providing a high-luminance full-color device.

Electroluminescence (EL) phenomenon can be caused even by a structure including a single layer of organic film sandwiched between electrodes. However, in order to increase the efficiency of carrier injection from the electrodes to the organic luminescence film so as realize a high luminescence at a lower applied voltage, it has been proposed to form a laminate structure including a carrier injection layer or a carrier transport layer between the electrodes and the organic luminescence layer.

Examples of the proposed laminate structures may include: anode/organic hole-transporting layer/organic luminescence layer/cathode (JP-A 57-51781), anode/organic luminescence layer/organic electron-transporting layer/cathode (C. Adachi, T. Tsutsui, S. Saito: Appl. Phys. Lett., 55, 1489 (1989), and anode/plural organic hole-injecting and transporting layers/organic luminescence layer/plural election-injecting and transporting layers/cathode (JP-A 6-314594).

As electrode materials, transparent or translucent films of indium-tin-oxide (ITO) or gold foil are used as anodes for allowing light transmission, and films of magnesium, aluminum or indium optionally doped with silver, lithium etc., are used as cathodes (e.g., JP-A 5-121172).

Such a film laminate structure is generally poor in durability against moisture and heat and is therefore subjected to sealing as by covering entirely with a photocurable resin and applying a glass sheet thereto (JP-A 6-338392), by placing the structure within a vessel of glass, etc., having an injection port and injecting a liquid sealant through the injection port for sealing (JP-A 7-11247), or by covering with a laminate film which has been used as a means for sealing an inorganic EL device (JP-A 60-14798).

An example of conventional process for producing such an organic EL device is illustrated in FIGS. 6A-6F, wherein a cathode layer 2 comprising transparent electrodes is formed, e.g., by sputtering or vacuum deposition, on a transparent substrate 1 of glass or resin film (FIG. 6A), and is coated successively with an organic hole-transporting layer 3, an organic luminescence layer 4, an organic electron-transporting layer 5, etc., by known film-forming techniques, such as vacuum deposition, solution coating, LB (Langmuir-Blodget) technique, and screen printing (FIGS. 6B-6D), a getter 6 for moisture absorption is placed around and a metal cathode layer 7 is formed, e.g., by vacuum deposition or sputtering on the laminate structure (FIGS. 6D and 6E) and then the laminate structure is entirely covered with a rear cover 8 applied with a moisture-resistant adhesive agent 9 dispensed at peripheral parts of the substrate 1 surrounding the laminate structure forming a display region, followed by attachment of lead wires and sealing.

As for process for production of and organization of a full-color display panel using polymeric EL materials, JP-A 3-269995 discloses a production process according to printing, but details thereof have not been disclosed. JP-A 10-12377 discloses a production process utilizing ink jetting.

On the other hand, as for full-color display panels using low-molecular weight or monomeric EL materials, production processes utilizing vacuum deposition through a shadow mask for patterning are generally used as disclosed in U.S. Pat. No. 5,294,869, JP-A 5-258859, JP-A 5-258860 and JP-A 5-275172. According to these processes, however, it has been difficult to produce a high-definition full-color display panel because of the restriction by positional accuracy and aperture size of the shadow mask. For alleviating the difficulty, JP-A 9-167684 has proposed a process including a patterning method using a donor sheet but the process becomes complicated as a whole since it requires vacuum deposition for formation of luminescence layers.

In such conventional processes for production of organic EL devices wherein an anode layer, organic film layers and a cathode layer are sequentially laminated on a single substrate, a step of forming a metal cathode layer is included after formation of the organic film layers. However, it is generally difficult to uniformly form organic film layers, and the surface planarity of the resultant film layers changes with time and temperature, so that it becomes furthermore difficult to form a metal layer on the organic film layers. Further, even if the organic film layers are successfully uniformly formed, the subsequent metal layer formation thereon is liable to damage the organic film layers because of a high energy of the metal layer formation. These difficulties are led to fluctuation of laminate film layer thickness and occurrence of pinholes, resulting in a remarkable lowering in luminescence performances.

On the other hand, JP-A 6-283265 has proposed a process wherein a rear electrode and a luminescence layer are successively formed on a printing substrate of a plastic film, a transparent electrode substrate (of, e.g., a transparent plastic sheet) is superposed on the printing substrate, and the superposed structure is passed between hot-pressure rollers to combine or apply the electrode layer and the luminescence layer, thereby forming a laminate device structure.

Further, JP-A 9-7763 discloses a process for producing an organic film EL device having a laminate film structure comprising a number n (n≧1) of organic film layers disposed between an anode layer and a cathode layer and sandwiched between moisture-proof films, wherein a transparent anode layer and a number m (m≧0) among the n of organic film layers are successively laminated on one moisture-proof film, a cathode layer and the remaining n−m among the n of organic film layers are successively laminated on the other moisture-proof film, and then the both laminate films are disposed opposite to and combined or applied to each other, followed by sealing of the periphery of the structure by adhesion or melt-bonding. In the process, an organic film layer constituting the boundary of application among the laminate organic film layers is formed as a resinous dispersion film comprising an organic EL material dispersed in a resinous binder, and the combination or application is performed by press-bonding at a temperature where the resinous binder is softened.

However, the dispersion of an organic EL material in a binder resin is liable to remarkably lower then luminescence efficiency and the efficiency of injection or transportation of electrons or holes, thus increasing the amount of electricity for the operation. Further, the application of different layers is liable to result in a peeling at the application boundary.

### SUMMARY OF THE INVENTION

In view of the above-mentioned problem, an object of the present invention is to provide a process for producing an organic luminescence device which includes organic layers formed by mutual combination or application without a binder and exhibiting an improved boundary adhesion, and also exhibits stable luminescence efficiency and luminance, thus require a lower electricity consumption.

Another object of the present invention is to provided an organic luminescence display device produced through such a process.

According to the present invention, there is provided a process for producing an organic luminescence device including organic layers disposed between an anode and a cathode, comprising:

a step of forming a first organic layer over an anode already formed on a first substrate, a step of forming a second organic layer comprising an identical material forming the first organic layer over a cathode already formed on a second substrate, and

a combining step of disposing the first and second organic layers opposite to each other and applying the first and second organic layers to each other under pressure, followed by baking, to form a laminate organic luminescence device.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1A to 1C are schematic sectional views for illustrating a step of combining or applying organic layers to each other for preparing an organic luminescence device according to the invention.

FIGS. 2A to 2F are perspective views and FIGS. 2G to 2J are sectional views, for illustrating process steps for preparing passive full-color organic luminescence display devices according to Examples 1 and 2.

FIGS. 3A to 3F are perspective views, for illustrating process steps for preparing an active full-color organic luminescence display device according to Example 3.

FIGS. 4A and 4B are schematic side views for illustrating an offset printing step suitably used for formation of organic layers in the process of producing organic luminescence devices.

FIG. 5 is a schematic perspective view for illustrating an ink jet printing step suitably used for formation of organic layers in the process for producing organic luminescence device.

FIGS. 6A to 6F are sectional views for illustrating a conventional process for producing organic luminescence devices.

### DESCRIPTION OF THE PREFERRED EMBODIMENTS

Hereinbelow, some preferred embodiments of the present invention will be described with reference to drawings.

As described above, the process of the present invention allows the production of an organic luminescence device including organic layers disposed between an anode and a cathode.

In many cases, the organic layers disposed between the electrodes include: at least one of a hole-injecting layer and a hole-transporting layer, a luminescence layer, and at least one of an electron-injecting layer and an electron-transporting layer.

In this embodiment of the present invention, an organic luminescence device is prepared by providing two substrates each having an electrode and an organic layer, and combining or applying the organic layers to each other.

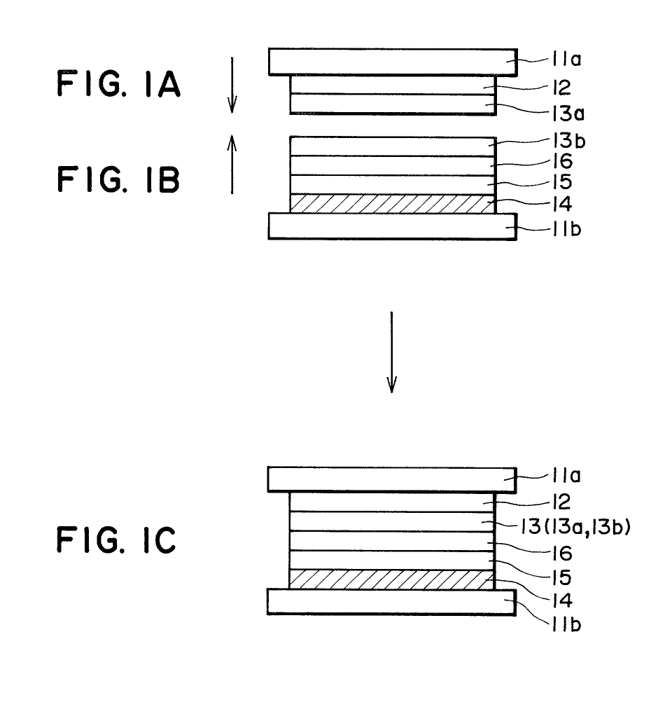

FIGS. 1A to 1C illustrate such an embodiment wherein a first substrate 11a is provided with an anode 12 and a hole-transporting layer 13a (as a first organic layer) successively formed thereon (FIG. 1A), another substrate 11b is provided with a cathode 14, an electron-transporting layer 15, a luminescence layer 16 and a hole-transporting layer 13b (as a second organic layer) successively formed thereon (FIG. 1B), the first and second substrates and 11a and 11b are disposed so that the hole-transporting layers 13a and 13b are disposed opposite to each other (FIGS. 1A and 1B), and the hole-transporting layers 13a and 13b comprising an identical material are combined or applied to each other to form a laminate organic luminescence device structure including a single hole-transporting layer 13 (FIG. 1C). The combination or application of such organic layers 13a and 13b comprising an identical material and therefore capable of providing identical surface states showing a higher affinity with each other than application of layers comprising different materials. The combination or application is moreover easily accomplished under heat supply.

The first and second organic layers comprising an identical material and combined to each other to form a single functional layer, may be any of the hole-injecting layer or hole-transporting layer, the luminescence layer, or the electron-injecting layer or electron-transporting layer, but may preferably be other than the luminescence layer. This is because compared with the luminescence layer formed in discrete sections each corresponding to one pixel, the other layers are respectively formed as a uniform layer covering the whole display area, so that the formation thereof by application of two identical layers becomes easier without a strict care of alignment. Further, a relatively thick layer may suitably be formed by application of two identical layers while this is not essential.

The laminated structure shown in FIG. 1C is subjected to baking under pressure for a prescribed period so as to unite the first and second organic layers 13a and 13b to form a substantially single, organic functional layer 13, while removing the solvent from the organic layers 12, 13 (13a and 13b), 16 and 15. As a result of the solvent removal, the bonding between the individual organic layers and between the organic layers and the electrodes is ensured without causing denaturation of the materials constituting the organic layers, thus allowing a long period of luminescence while effectively preventing the occurrence of dark spots. The heating temperature for the baking should be lower than the melting points of the organic materials constituting the organic layers, more preferably at or below the lowest one among the softening or glass-transition temperatures of the organic materials constituting the organic layers, which generally range from about 80 to 160° C. As the actual softening temperatures of the respective organic layers can be varied with the content of the solvent therein, the heating temperature may preferably be suppressed to at most 80° C. For convenience of control, it is preferred to use a temperature of at least 40° C., while the drying can proceed even at a lower temperature. The drying under heating may for example be effected by oven drying, hot plate heating, or vacuum drying.

The organic layers 13a and 13b formed by solution application on the first and second substrates 11a and 11b can be directly subjected to the combination or application, followed by baking, but either one or both of the organic layers to be bonded to each other may preferably be separately subjected to pre-baking at a temperature below the baking temperature for short period for evaporating a portion of the solvent contained in the organic layers while leaving a wet state of the organic layers. The pre-baking treatment is particularly preferred for completing the drying in the subsequent baking step in the case of producing a large-area device. As a certain wet state is retained after the pre-baking, the combination or application with each other of the organic layers 13a and 13b is not hindered but rather promoted. The pre-baking treatment may be effected by oven drying, hot plate drying, vacuum drying, etc.

After the baking, peripheral parts surrounding the display region of the substrates 1a and 1b are bonded to each other with an adhesive applied thereat. The adhesive may preferably be a moisture-proof one and particularly preferably be an ultraviolet-curable adhesive compared with a heat-curable adhesive which generally requires a curing temperature as high as 140-180° C., adversely affecting the resultant device performances. Alternately, it is also possible to use a flexible and thermobondable (or sealable) resin for the substrate for sealing at parts surrounding the display region.

Further, it is also possible to dispose a moisture getter within the sealed region on the substrates for suppressing the deterioration of the resultant device. For example, a moisture getter, such as powdery calcium oxide or zeolite, may be applied at parts surrounding the display region on either one or both of the substrates.

Examples of organic luminescence materials may include: triarylamine derivatives, stilbene derivatives, polyarylenes, aromatic condensed polycyclic compounds, aromatic heterocyclic compounds, metal complex compounds, and simple and complex oligomers of these, but there are not exhaustive.

Further, as mentioned above, an organic hole injection/transportation layer and/or an organic electron injection/transportation layer may be disposed between the electrodes and the organic luminescence layer for the purpose of reducing the energy barrier between the electrodes and the organic luminescence layer and promoting carrier transfer to the organic luminescence layer.

Examples of the hole injection/transportation material may include: soluble phthalocyanine compounds, triarylamine compounds, electroconductive polymers, perylene compounds and Eu complexes, but these are not exhaustive.

A hole-transporting layer may also be formed as a layer of polyphenylenevinylene by heating of a coating layer of polytetrahydrotripheylphenylene, for example.

Examples of the electron injection/transportation material may include: Alq₃ formed by coordination of 8-hydroxyquinoline trimmer onto aluminum, azomethine zinc complex and distyrylbiphenyl derivatives, but these are not exhaustive.

Each organic film layer may be formed in a thickness of ca. 0.05-0.3 μm, preferably ca. 0.1-0.2 μm. This thickness refers to a thickness after (prebaking), combining and baking of the first and second organic layers if the organic layer concerned is formed through such steps. Anyway, each organic layer formed through a wet process, such as solution application, can exceed the thickness range since the thickness thereof can be reduced due to solvent evaporation during the pre-baking and baking.

The wet process for forming or lamination of an organic layer may be achieved by coating or printing, and a specific method may be appropriately selected depending on the viscosity and manner of drying of the solution to be applied.

The coating may be achieved by spin coating, transfer coating, extrusion coating etc. In view of material utilization efficiency, a method allowing pattern coating for leaving a film free marginal region around the display region, such as the transfer coating or the extrusion coating, is preferred, and the transfer coating is particularly preferred.

The printing may be achieved by screen printing, offset printing, ink jet printing, etc. For formation of pixels of a luminescence layer through a wet process including superposition of R, G and B patterns, a high accuracy and high resolution printing, such as offset printing or ink jet printing, is preferred. These printing processes can also be used for application of other organic layers for leaving a marginal film-free region.

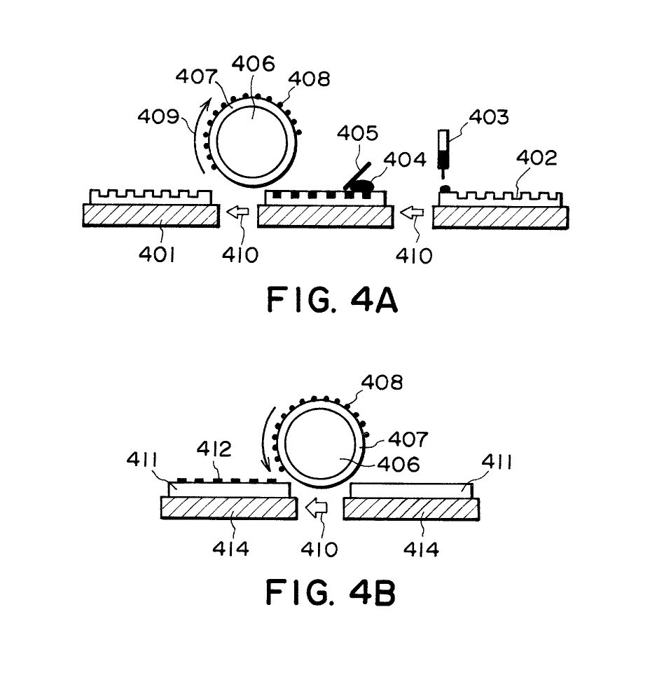

As for an offset press, a sheet-fed proof press is basically used. A machine that has been reformed for allowing a better printing accuracy and better accuracy of setting printing conditions compared with an ordinary waterless offset press or an ordinary gravure press, may preferably be used. FIG. 4A and 4B illustrate such an offset printing process. Referring to FIG. 4A, onto a gravure plate 402 set on a stage 401, an ink 404 of organic luminescent material is dropped from a dispenser 403 and charged into the recesses of the gravure plate 402 while being scraped off by a doctor blade 405. Then, a blanket 407 wound about a cylinder 406 rotated in a direction 409 and caused to contact the plate 402 under a prescribed pressure, thereby receiving the ink carried on the plate 402 to form an ink pattern 408 thereon (FIG. 4A). Then, the blanket 407 carrying the ink pattern 408 is caused to contact a substrate 411 of the organic luminescence device set on a stage 414 under a prescribed pressure, whereby the ink pattern 408 on the blanket 407 is transferred and printed as an ink pattern 412 on the substrate 411 (FIG. 4B).

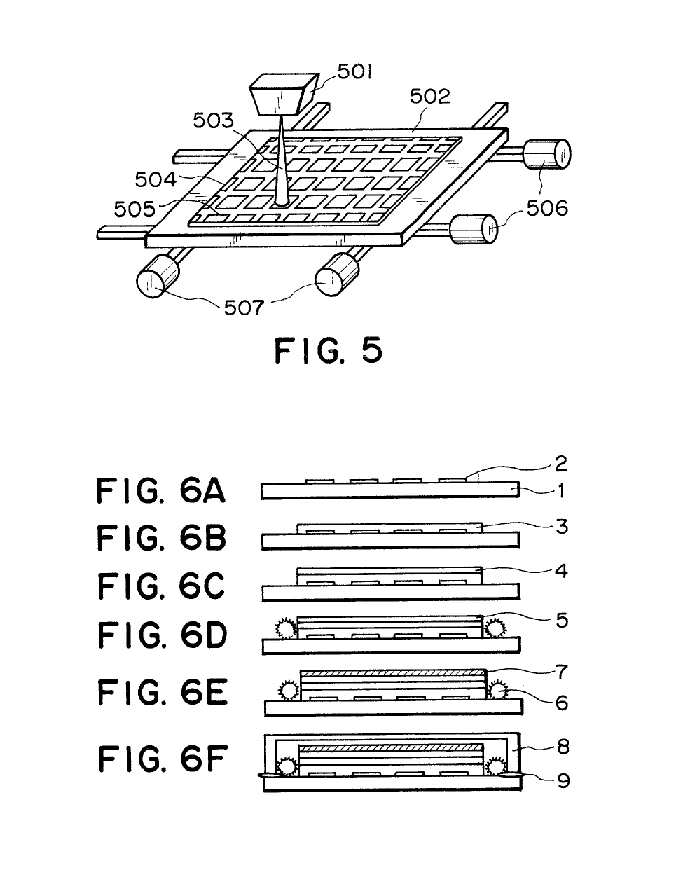

FIG. 5 illustrates an example of ink jet printing system suitable for forming luminescence pixels on a substrate. The ink jet printing system shown in FIG. 5 allows an accurate horizontal movement of a substrate 504 of, e.g., glass, and ejection of an ink onto a desired position on the substrate 504 according to a so-called stepper or step-and-repeat mechanism. More specifically, referring to FIG. 5, the system includes an ink jet head 501 for ejecting an ink 503, a glass substrate 504 set on the stage 502, an X-axis drive mechanism 506 and a Y-axis drive mechanism 507. While moving the substrate 504 in longitudinal and transversal directions (X- and Y-axes) by the drive mechanisms 506 and 507, followed by setting the substrate 504 in position, an ink 503 is ejected out of the ink head 501 onto an exact position (i.e., a pixel) on the substrate. This printing step is repeated while moving the substrate 504 longitudinally and transversely, thereby forming pixels of luminescence materials while leaving partitioning stripe regions 505 which may also be covered with a (black) masking ink as desired. The ink jet head 501 may be of either a bubble jet type (thermal type) or a piezoelectric jet type. The ejected ink may preferably be formed by dissolving of an organic layer-forming material in a solvent having a boiling point of at least 70° C. Examples of such an ink may include: NMP (N-methyl-2-pyrrolidone), BCA (diethylene glycol mono-n-butyl ether acetate), DBP (di-n-butyl phthalate), CA (diethylene glycol monoethyl ether acetate) and PGMIA (propylene glycol-1-monomethyl ether acetate), but these are not exhaustive.

For forming the inks or solutions of organic layer-forming materials to be applied through a wet process, in general, such an organic layer-forming material may preferably be dissolved in a solvent having a boiling point of at least 70° C. Examples of the solvent may include: NMP, BCA, DBP, CA and PGMIA, mentioned above, and also toluene, xylene and MEK (methyl ethyl ketone). These are however not exhaustive. An appropriate solvent may be selected depending on an organic layer-forming material to be dissolved therein. The organic layer-forming materials used in providing organic layers do not generally have a very high solubility in such an organic solvent, as low as one to second percent, or even lower. However, an ink of such an organic layer-forming material at a low concentration is preferable so as to form a thin organic layer of, e.g., 0.1-0.2 μm. Moreover, such a small dissolving power of an organic solvent is also preferred in view of lamination of various organic layers through a wet process.

Referring again to FIGS. 1A to 1C, the anode 12 may be formed of an electroconductive material, such as ITO (indium tin oxide), IZO (indium zinc oxide), SnO₂, etc., which may preferably be light-transmissive. A transparent electrode of ITO is particularly preferred. Such a transparent electrode may be formed and patterned by mask vapor deposition or vapor deposition followed by a lithographic patterning process, for example.

The cathode 14 may preferably comprise a metal, such as Al, Ag, Au, Cu or an alloy of these metals with another additive metal. The cathode 14 may be formed in a pattern by mask vapor deposition, vapor deposition or plating optionally followed by photolithographic patterning or printing. These are however not exhaustive.

As briefly mentioned with reference to FIG. 5, the respective pixels may be separated from each other with light-interrupting partitioning stripes or matrix (so-called black matrix), which may for example comprise Cr (chromium) or a colored (typically black) resin. Chromium mask (or stripes) may for example be patterned through a photolithographic process, and a colored resin matrix may for example be formed through a photolithographic process or printing. The chromium mask is required to be insulated from the electrodes. The resin matrix should be provided with a high resistivity by appropriately selecting (the species and/or amount) of a pigment (of, e.g., carbon-based).

The resin constituting the resin partitioning matrix may preferably be resistant to an organic luminescent material or a solvent therefor and may preferably be a thermocurable or photocurable resin, such as epoxy resin or acrylic resin, optionally colored with a black colorant for enhancing the light-interrupting function. The resin mask may suitably be formed in the required pattern through offset printing or photolithography.

Each functional organic layer constituting the organic luminescence device of the present invention should preferably be prevented from containing impurities exceeding 30 wt. % thereof, so as to prevent an adverse effect to the device.

Each functional organic layer should be further free from a binder component different from the functional material concerned, such as the luminescence material or the charge injection or transporting material.

The organic luminescence device of the present invention may be formed into a full-color display device by forming the pixels as a combination of three colors of R, G and B arranged in a prescribed pattern.

Hereinbelow, the present invention will be described more specifically with reference to Examples, which should not be however construed to restrict the scope of the present invention.

### EXAMPLE 1

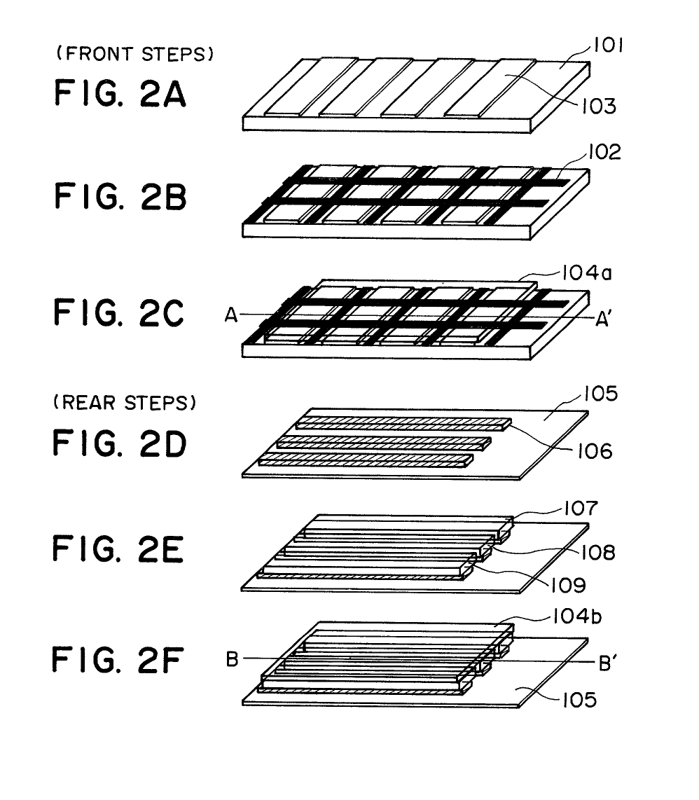

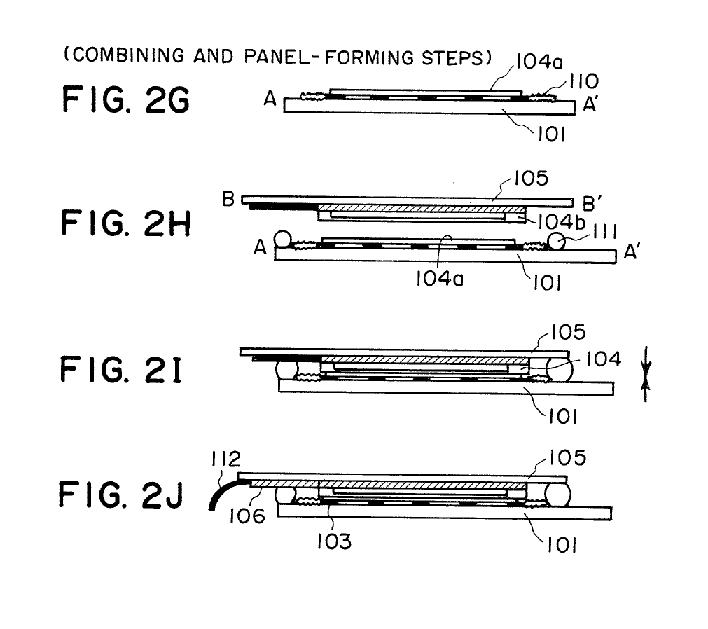

A direct viewing-type passive full-color organic luminescence display device was prepared through steps as shown in FIGS. 2A through 2J.

Referring to these figures, a glass substrate 101 (as a front substrate) of 360 mm×460 mm in planar size was first provided with ITO transparent electrodes 103 by vacuum deposition (FIG. 2A) and then provided with a resinous black matrix 102 of a high-resistivity black resist (made by Fuji Film Olin K.K.) through a lithographic process (FIG. 2B). Separately, triphenylamine hexamer (abbreviated as TPA-6; M.W. (molecular weight)=1461, Tmp (melting point)=277° C., Tg=156° C.) was dissolved in toluene to form a 0.5 wt. %-conc. solution, which was then applied in a thickness of ca. 10 μm over an area of 350 mm×450 mm by an extrusion coater (“α-COATER”made by FAS Co.) as a first hole-injection layer 104a (FIG. 2C). The thus-treated front substrate was stored in a dry nitrogen gas atmosphere.

Separately, a rear glass substrate 105 was provided with Al metal electrodes 106 (FIG. 2D), and then provided 0.05 μm-thick luminescence layers 107, 108 and 109 emitting red, green and blue colors (R, G and B), respectively, by using an offset printing system as illustrated in FIGS. 4A and 4D (FIG. 2E). The R-luminescence layer 107 comprised 9, 9-dioctylfluorenone pentamer (DOFL-5; Mw=1945, Tmp=210° C., Tg=123° C.); the G-luminescence layer 108, DOFL-5 doped with 1.0 wt. % of coumarin; and the B-luminescence layer 109, DOFL-5 doped with 1.0 wt. % of 4-dicyanomethylene-2-methyl-6-(4-dimethylaminostyryl-)4-H-pyran (DCM) by using a 0.5 wt. % solution in toluene of each luminescence material.

The rear substrate 105 provided with the luminescence layers 107-109 was then coated with a 0.5 wt. %-solution in toluene of TPA-6 by extrusion coating to form a second hole-injection layer 104b thereon, and stored in a dry nitrogen atmosphere (FIG. 2F).

Then, a powdery getter 110 of calcium oxide was applied at peripheral parts on the front substrate 101 (FIG. 2G), and further a moisture-proof adhesive 111 was applied therearound and the rear substrate 105 coated with the second hole-injection layer 104b was superposed over the front substrate 101 thus treated (FIG. 2H). Further, the first and second hole-injection layers 104a and 104b were applied to each other under a pressure of 1 MPa, and then baked at 80° C. to form an integral hole-injection layer 104 having a thickness of ca. 0.09 μm as measured by an AFM (FIG. 2I). Finally, the anodes 103 on the front substrate 101 and the cathodes 106 on the rear substrate 105 were respectively connected with lead wires 112 (only one being shown) to complete a direct viewing-type passive full-color organic luminescence display device (FIG. 2J).

### EXAMPLE 2

A direct viewing-type passive full-color organic luminescence display device was prepared through steps as shown in FIGS. 2A through 2J, similarly as in Example 1, except that a pre-baking step was inserted before the application of the two substrates.

Thus, referring to FIGS. 2A-2J, a glass substrate 101 (as a front substrate) was first provided with ITO transparent electrodes 103 by vacuum deposition (FIG. 2A) and then provided with a resinous black matrix 102 of a high-resistivity black resist (made by Fuji Film Olin K.K.) through a lithographic process (FIG. 2B). Separately, a 0.5 wt. % in toluene of TPA-6 was applied by extrusion coating. The thus-treated front substrate 101 was prebaked at 40° C. to form a 0.05 μm-thick first hole-injection layer 104a (FIG. 2C) and stored in a dry nitrogen gas atmosphere.

Separately, a rear glass substrate 105 was provided with Al metal electrodes 106 (FIG. 2D), and then provided with 0.05 μm-thick luminescence layers 107, 108 and 109 emitting red, green and blue colors (R, G and B), respectively, by using an offset printing system as illustrated in FIGS. 4A and 4D (FIG. 2E). The R-luminescence layer 107 comprised DOFL-5; the G-luminescence layer 108, DOFL-5 doped with 1.0 wt. % of coumarin; and the B-luminescence layer 109, DOFL-5 doped with 1.0 wt. % DCM.

The rear substrate 105 provided with the luminescence layers 107-109 was then coated with a 0.5 wt. %-solution in toluene of TPA-6 by extrusion coating, prebaked at 40° C. to form a 0.05 μm-thick second hole-injection 104b thereon, stored in a dry nitrogen atmosphere (FIG. 2F).

After providing the getter 110 and the moisture-proof adhesive 111, the rear substrate 105 coated with the second hole-injection layer 104b was superposed over the front substrate 101 thus treated (FIG. 2H). Further, the first and second hole-injection layers 104a and 104b were applied to each other under pressure, and then baked at 80° C. to form an integral hole-injection layer 104 having a thickness of ca. 0.09 μm (FIG. 2I). Finally, lead wires 112 (only one being shown) were connected to the anodes 103 and the cathodes to complete a direct viewing-type passive full-color organic luminescence display device (FIG. 2J).

### EXAMPLE 3

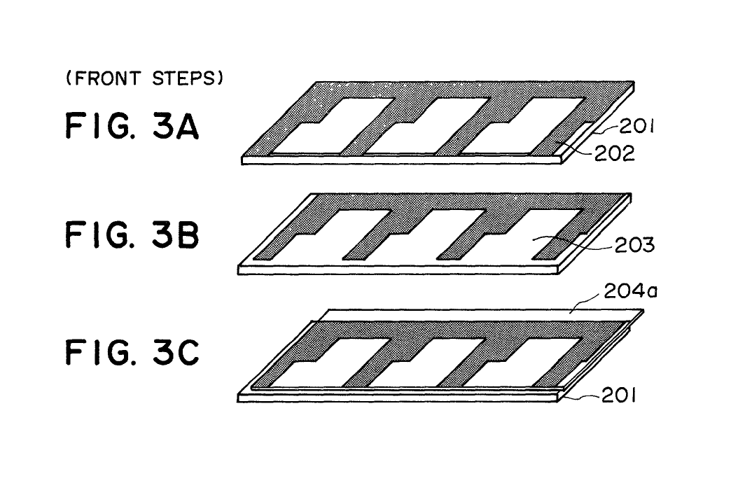

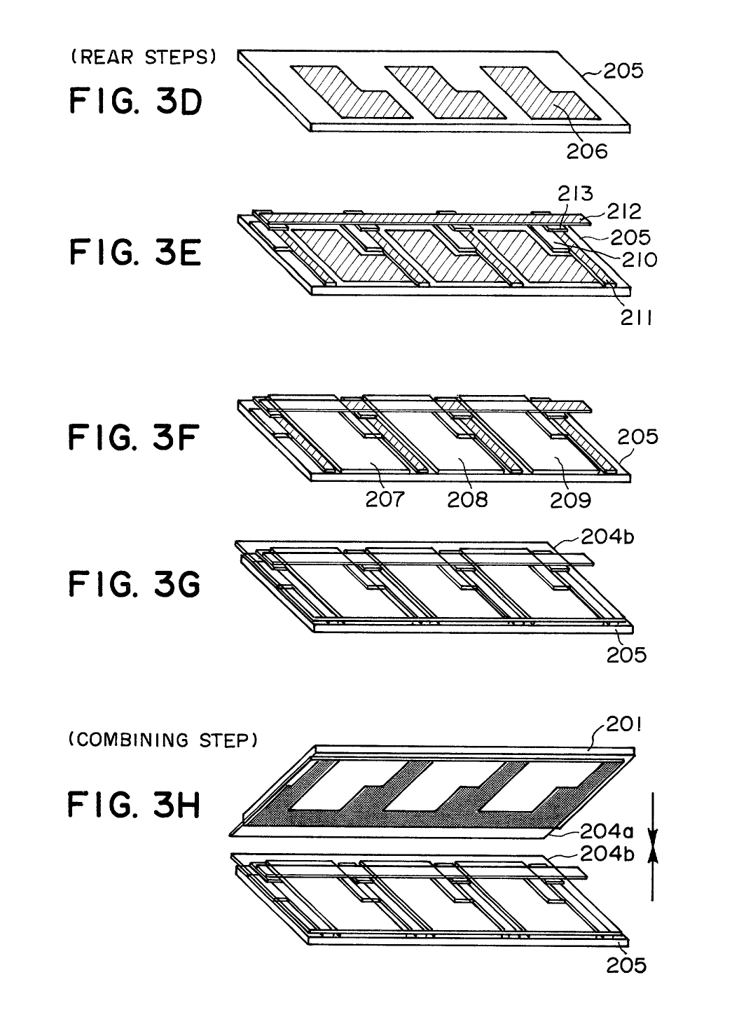

A direct viewing-type passive full-color organic luminescence display device was prepared through steps as shown in FIGS. 3A through 3H.

Referring to these figures, a glass substrate 201 (as a front substrate) was first provided with a resinous black matrix 202 of a high-resistivitity black resist (made of Fuji Film Olin K.K.) (FIG. 3A) and then with ITO transparent electrodes 203 by vacuum deposition (FIG. 3B), which was then coated by extrusion coating with a 0.5 wt. %-solution in toluene of TPA-6, followed by pre-baking at 40° C., to form a 0.05 μm-thick first hole-injection layer 204a (FIG. 4C). The front substrate 201 thus-treated was then stored in a dry nitrogen atmosphere.

Separately, a rear glass substrate 205 was first provided with metal electrodes 205 each having a laminate structure of an Al—Li alloy layer on an Al layer (FIG. 3D), and then successively provided with thin film transistors 210, data electrodes 211, an insulating layer 213 and scanning electrodes 212 respectively in prescribed patterns (FIG. 3E).

Then, respective pixels separated from each other by the electrodes 211 and 212 were provided with 0.05 μm-thick R-luminescence layer 207, G-luminescence layer 208 and B-luminescence layer 209, respectively, by ejection of inks of the corresponding inks by using an ink printing system as illustrated in FIG. 5, (FIG. 3F). The R-luminescence layer 207 comprised DOFL-5 ; the G-luminescence layer 208, DOFL-5 doped with 1.0 wt. % coumarin; and the B-luminescence layer 209, DOFL-5 doped with 1.0 wt. 5 of DSM.

Then, the rear substrate provided with the luminescence layer patterns 207-209 was then coated with a 0.5 wt. %-solution in toluene of TPA-6 by extrusion coating, prebaked at 40° C. to form a 0.05 μm-thick second hole injection layer 204b (FIG. 3G), and stored in a dry nitrogen atmosphere.

After providing a getter and a moisture-proof adhesive at peripheral parts on the front substrate 201 in a manner similar to that illustrated in FIGS. 2G and 2J, the front substrate 201 was superposed on the above-treated rear substrate 205 with the first and second hole-injection layers 204a and 204b facing each other (FIG. 3H), followed by application and baking under pressure to form a ca. 0.09 μm-thick integrated hole-injection layer. Finally, lead wires were connected to the respective electrodes, similarly as in Example 1, to complete a direct viewing-type passive full-color organic luminescence display device.

As described above, according to the present invention, partial organic layers comprising identical functional materials free from binders are formed on a pair of substrates having the other functional layers constituting an organic luminescence device, and thin applied to each other to form a substantially single function organic layer, thereby easily providing an organic luminescence device with an improved adhesion at the boundary. As the charge injection and transportation are not obstructed by the binders, the resultant organic luminescence device is provided with advantageous features, such as stabilized luminescence efficiency and luminance and reduced power consumption.

What is claimed is:

1. A process for producing an organic luminescence device including organic layers disposed between an anode and a cathode, comprising:
a step of forming a first organic layer over an anode already formed on a first substrate,
a step of forming a second organic layer comprising an identical material forming the first organic layer over a cathode already formed on a second substrate, and
a combining step of disposing the first and second organic layers opposite to each other and applying the first and second organic layers to each other under pressure, followed by baking, to form a laminate organic luminescence device.

2. A process according to claim 1, wherein the combining step includes a step of bonding the first and second substrates at peripheral parts thereof surrounding the first and second organic layers by adhesion or melt-bonding.

3. A process according to claim 1, further including a step of pre-baking at least one of the first and second organic layers prior to the combining step.

4. A process according to claim 1, wherein in the combining step, the first and second organic layers are baked at a temperature lower than a lowest softening temperature of the organic layers.

5. A process according to claim 3, wherein in the pre-baking step, said at least one of the first and second organic layers is subjected to heating at a temperature below a lowest softening temperature of the organic layers concerned.

6. A process according to claim 1, wherein the first and second organic layers both comprise a hole-transporting or hole-injection material.

7. A process according to claim 1, wherein the first and second organic layers both comprise an electron-transporting or electron-injecting material.

8. A process according to claim 1, wherein first and second organic layers both comprise a luminescence material.

9. A process according to claim 1, wherein the first and second organic layers are both formed through a wet process.

10. A process according to claim 1, wherein a step of forming a luminescence layer in mutually discrete pixels is included prior to the combining step, and the first and second organic layers other than the luminescence layer are applied to each other in the combining step.

11. A process for producing an organic luminescence device including organic layers disposed between an anode and a cathode, comprising:
a step of forming a first organic layer over an anode already formed on a first substrate,
a step of forming a second organic layer comprising an identical material forming the first organic layer over a cathode already formed on a second substrate,
a step of pre-baking at least one of the first and second organic layers, and
a combining step of disposing the first and second organic layers opposite to each other and applying the first and second organic layer to each other under pressure, followed by baking, to form a laminate organic luminescence device.

12. An organic luminescence device produced through a process according to claim 1.
